(19) United States
(12) Patent Application Publication
(10) Pub. No.: US 2005/0101124 A1
(43) Pub. Date: May 12, 2005

(54) Via contact forming method

(75) Inventors: Chang-Ming Wu, Jhonghe City (TW); Shing-Yih Shih, Jhonghe City (TW); Yi-Nan Chen, Taipei (TW)

Correspondence Address: BACON & THOMAS, PLLC, 625 SLATERS LANE, FOURTH FLOOR, ALEXANDRIA, VA, 22314, US

(73) Assignee: NANYA Technology Corporation, Taoyuan (TW)

(21) Appl. No.: 10/702,493

(22) Filed: Nov. 7, 2003

(51) Int. Cl. H01L 21/4763

(52) U.S. Cl. 438/637; 438/640

(57) ABSTRACT

A via contact forming method. The method includes the steps of providing a substrate; forming a first dielectric layer on the substrate; forming a bit line in the first dielectric layer; forming a liner layer on the first dielectric layer containing the bit line; forming a second dielectric layer on the liner layer; in the second dielectric layer, forming a contact hole leading to the bit line; and filling the contact hole with metal to form a via contact. The via contact forming method in accordance with the present invention has high tolerance to misalignment between the via contact and the bit line, while maintaining low resistance and good electric performance.

### BACKGROUND OF THE INVENTION

1. Field of the Invention

The present invention relates to a semiconductor device process, more specifically, to a process for via contact in semiconductor device, which can tolerate misalignment.

2. Description of the Prior Art

In the semiconductor device process, the formation for via contacts plays an important role. As semiconductor devices are getting more and more compact, the critical dimensions of bit lines, via contacts and the like are also getting smaller and smaller. Accordingly, alignment is more difficult to achieve.

In the prior art semiconductor process for DRAM, for example, the process for forming a via contact will be described with reference to FIG. 1. As shown in FIG. 1a, a first dielectric layer 11 is formed on a substrate 10. The first dielectric layer 11 can be an oxide layer, and the material thereof comprises TEOS, for example. Subsequently, photoresist 12 is formed on the first dielectric layer 11, as shown in FIG. 1b. By performing steps of etching, filling with metal and so on, a conductive wire, such as a bit line 13, is formed. The material of the bit line 13 can be W wrapped with TiN/Ti, as shown in FIG. 1c. Then, the protruding portion of the bit line 13 is planarized by CMP, as shown in FIG. 1d.

With reference to FIG. 1e, a second dielectric layer 14 is formed on the structure of FIG. 1d. The second dielectric layer 14 can be an oxide layer. Then, photoresist 15 is formed on the second dielectric layer 14. By proper etching, a via contact hole is formed. The formed via contact hole is filled with conductive material, such as TiN/Ti/W, so as to form a via contact 16, as shown in FIG. 1f.

FIG. 1f shows the ideal situation, that is, the via contact 16 aligns well with the bit line 13. However, as mentioned above, misalignment between the via contact and the bit line often occurs. FIG. 1f′ shows a situation wherein the via contact 16′ does not align with the bit line 13.

In prior art, there are two conditions happening under the circumstance in which the via contact 16′ does not align well with the bit line 13. As shown in the drawing, when the via contact 16′ does not align well with the bit line 13, the contacting area between the via contact 16′ and the bit line 13 becomes small, thereby causing the resistance to increase. If the condition of misalignment is very serious, even the disconnection between the via contact and the bit line is likely to happen. Alternatively, in the process for the formation of the via contact hole, when the via contact hole does not align with the bit line, if over-etch occurs during etching the second dielectric layer 14 to form the via contact hole, a portion of the first dielectric layer 11, which is also made of oxide as the second dielectric layer 14, will be etched off or even penetrated, as indicated by the dash line in FIG. 1f′. After the via contact hole is filled with conductive material such as metal to form a via contact, the contacting area between the via contact and the bit line is increased since the side portion of the bit line contacts the via contact. However, the profile of the via contact 16′ is degraded, and even the bit line 13 is improperly connected with substrate 10 by the via contact 16′, thereby causing the electric performance of the whole structure to deteriorate.

Therefore, there is a need for a solution to overcome the problems stated above. The present invention satisfies such a need.

### SUMMARY OF THE INVENTION

An objective of the present invention is to provide an improved via contact forming method, which can tolerate a considerable degree of misalignment between the via contact and the bit line, and simultaneously maintain low resistance and good electric performance.

According to an aspect of the present invention, a via contact forming method comprises steps of providing a substrate; forming a first dielectric layer on said substrate; forming a conductive wire in said first dielectric layer; forming a liner layer on said first dielectric layer and said conductive wire; forming a second dielectric layer on said liner layer; forming a contact hole in said second dielectric layer to lead to said conductive wire; and filling said contact hole with conductive material.

According to another aspect of the present invention, the via contact forming method further comprises a step of removing a portion of said first dielectric layer to make the conductive wire protrude before forming said liner layer.

According to a further aspect of the present invention, in the via contact forming method, the material of said liner layer is different from the material of the first dielectric layer and the second dielectric layer.

According to still another aspect of the present invention, in the via contact forming method, the forming of the contact hole is completed by two-stage etching process.

### BRIEF DESCRIPTION OF THE DRAWINGS

The following drawings are only for illustrating the mutual relationships between the respective portions and are not drawn according to practical dimensions and ratios. In addition, the like reference numbers indicate the similar elements.

FIGS. 1a to 1f illustrate the respective steps for forming a via contact in prior art;

FIG. 1f′ shows a condition in which a formed via contact does not align with a bit line well in the prior art via contact forming method;

FIGS. 2a to 2i illustrate the respective steps for forming a via contact in accordance with the present invention; and

FIG. 2h′ shows a condition in which a formed via contact does not align with a bit line well in the via contact forming method of the present invention.

### DETAILED DESCRIPTION OF THE PREFERRED EMBODIMENT

An embodiment of the present invention will be described in detail with reference to the accompanying drawings.

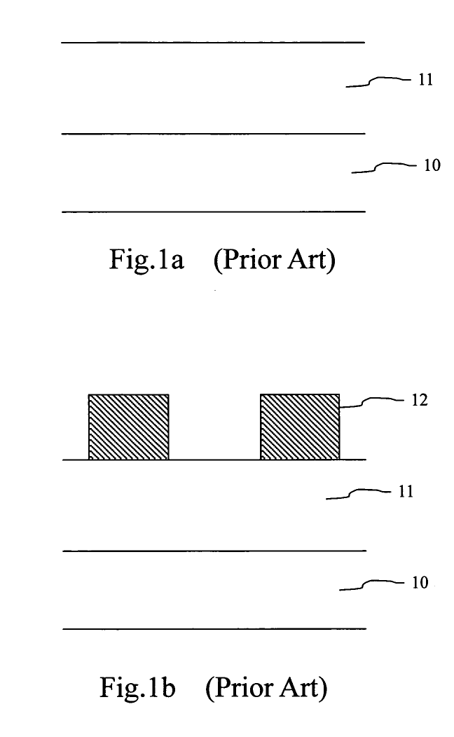

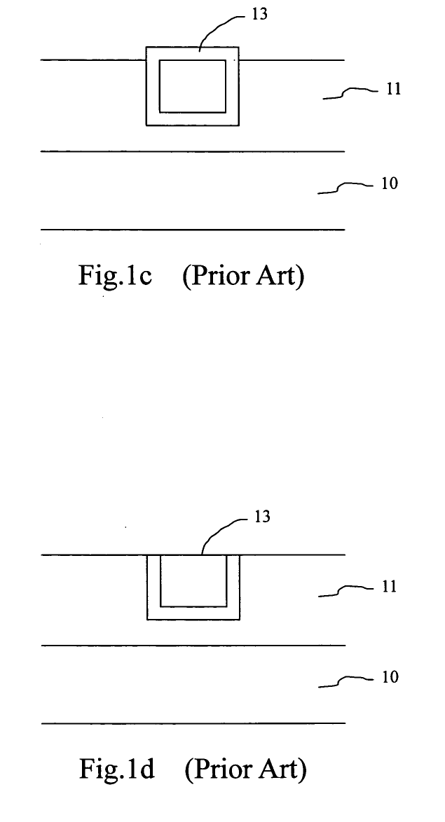

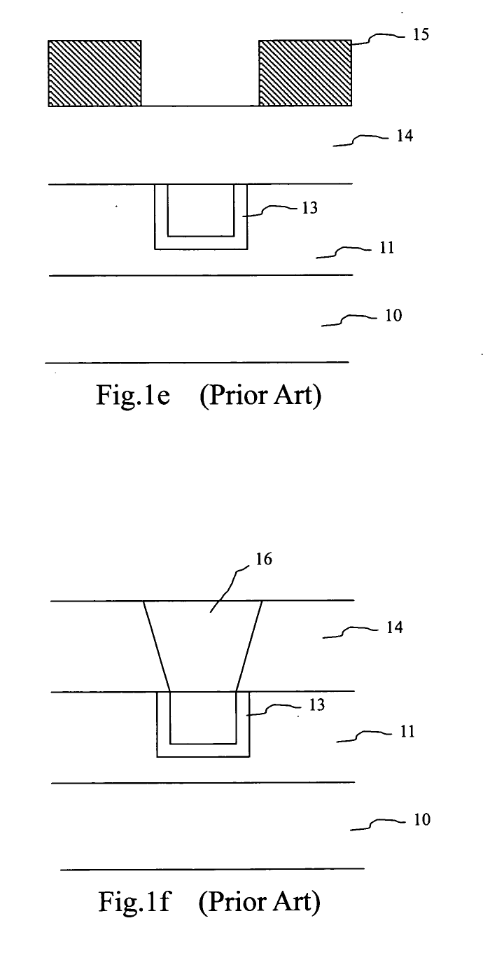

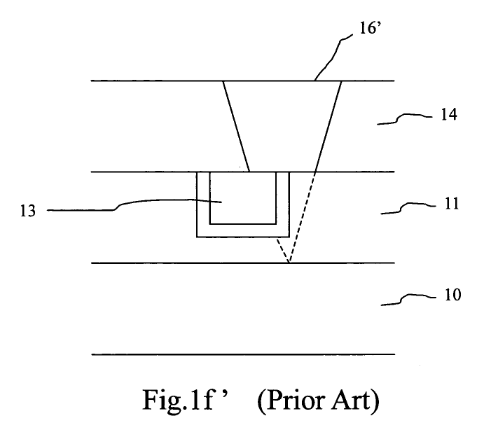

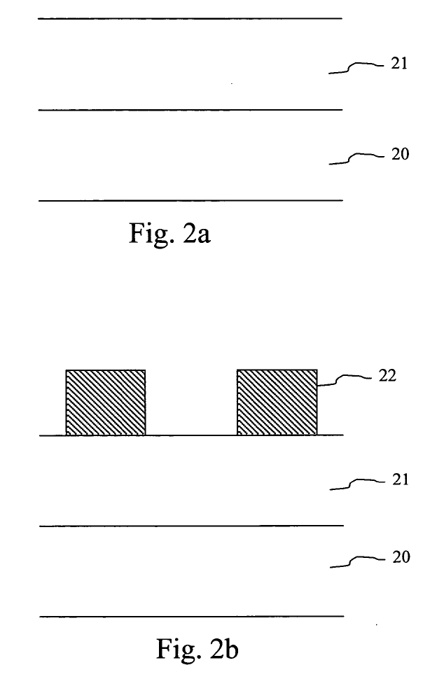

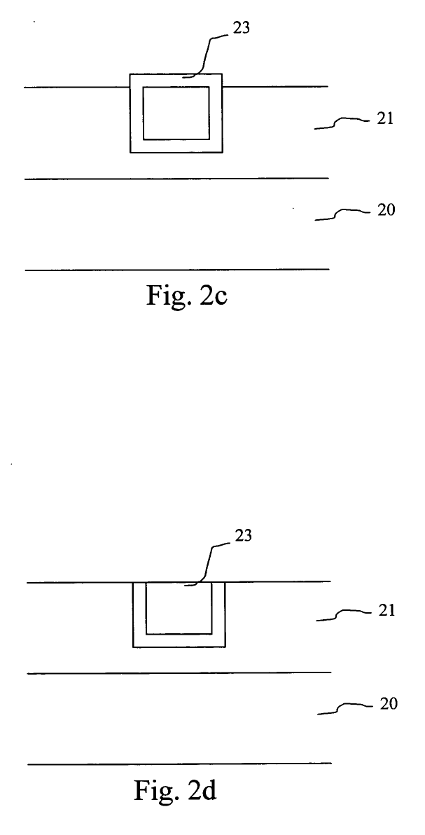

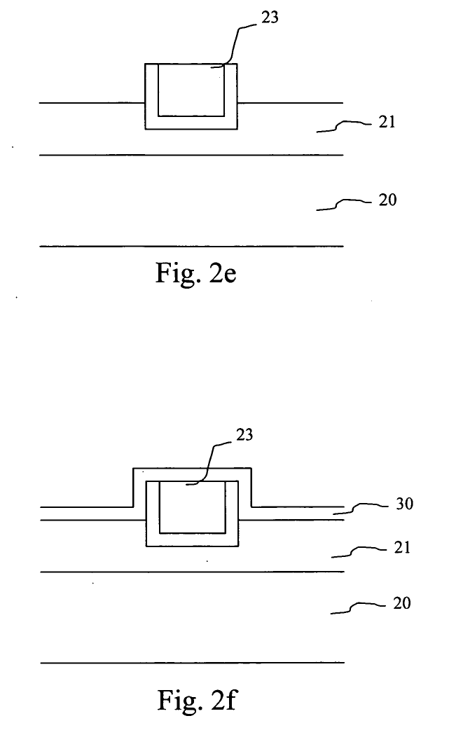

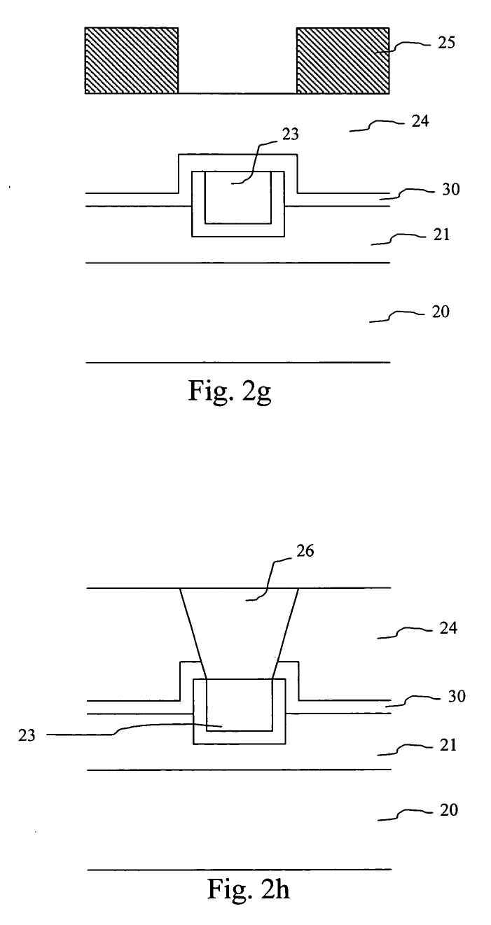

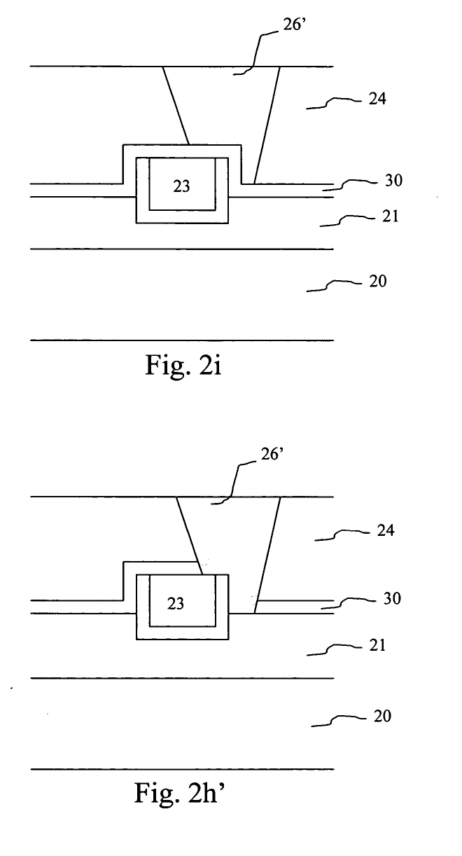

FIGS. 2 show the respective step of a via contact forming method in accordance with the present invention. The steps shown in FIGS. 2a to 2d are the same as those shown in FIGS. 1a to 1d, and therefore the relevant descriptions are omitted herein for simplification. In FIGS. 2a to 2d, reference number 20 indicates the substrate, 21 indicates the first dielectric layer, 22 indicates the photoresist, and 23 indicates the bit line.

After implementing planarization process for the bit line 23, the first dielectric layer 21 is partially removed, as shown in FIG. 2e. Subsequently, a thin liner layer 30 is formed on the partially removed first dielectric layer 21 and the bit line 23, as shown in FIG. 2f. The material of the liner layer 30 is different from that of the first dielectric layer 23, which is oxide (e.g. TEOS). According to the present embodiment, the liner layer can be a nitride layer. For example, the material of the liner layer comprises SiN.

Then, a second dielectric layer 24 is formed on the liner layer 30. The material of the second dielectric layer 24 can be oxide material. Then, as shown in FIG. 2g, photoresist 25 is formed on the second dielectric layer 24 to define the position where a via contact hole is to be formed. Finally, the via contact hole is formed by etching, and the formed via contact hole is filled with conductive material such as metal to form a via contact 26. FIG. 2h shows an ideal condition in which the formed via contact 26 aligns well with the bit line 23.

It is noted that the etching process for forming the via contact hole includes two steps. First, an etchant, such as plasma gas, with an etching selectivity sufficiently high for oxide/nitride is selected for etching to remove the portion of the second dielectric layer 24. The liner layer 30, of which the material is preferably SiN, functions as an etch stop layer for preventing the first dielectric layer 21 from being etched. Then, an etchant (plasma gas) with an etching selectivity sufficiently high for nitride/oxide is used to remove the portion of the liner layer 30 at the bottom of the via contact hole, and whereby the formation of the via contact hole is completed.

FIG. 2h′ shows a condition in which the via contact 26′ does not align well with the bit line 23. As shown, the via contact formed according to the present invention contacts the bit line with a large contact area even when the via contact does not align with the bit line well. In addition, the first dielectric layer is prevented from being etched even if over-etching happens during the formation of the via contact hole, so as to maintain the good profile of the via contact.

While the embodiment of the present invention is illustrated and described, various modifications and alterations can be made by persons skilled in this art. The embodiment of the present invention is therefore described in an illustrative but not restrictive sense. It is intended that the present invention may not be limited to the particular forms as illustrated, and that all modifications and alterations which maintain the spirit and realm of the present invention are within the scope as defined in the appended claims.

1. A via contact forming method comprising steps of:
providing a substrate;
forming a first dielectric layer on said substrate;
forming a conductive wire in said first dielectric layer;
forming a liner layer on the conductive wire and the first dielectric layer;
forming a second dielectric layer on said liner layer;
forming a contact hole in said second dielectric layer to lead to the conductive wire; and
filling said contact hole with a conductive material.

2. The via contact forming method as claimed in claim 1, further comprising a step of partially removing the first dielectric layer to make the conductive wire protrude before forming the liner layer.

3. The via contact forming method as claimed in claim 1, wherein material of the liner layer is different from that of the first dielectric layer and the second dielectric layer.

4. The via contact forming method as claimed in claim 3, wherein the material of the first dielectric layer and the second dielectric layer comprises an oxide, and the material of the liner layer comprises a nitride.

5. The via contact forming method as claimed in claim 4, wherein the material of the liner layer comprises silicon nitride.

6. The via contact forming method as claimed in claim 3, wherein the step of forming the contact hole comprises the following sub-steps:
removing a predetermined portion of the second dielectric layer by a first etching; and
removing a predetermined portion of the liner layer by a second etching.

7. The via contact forming method as claimed in claim 6, wherein the first etching uses an etchant with a high selectivity to the second dielectric layer with respect to the liner layer, and the second etching uses an etchant with a high selectivity to the liner layer with respect to the first dielectric layer.
